(19) United States
(12) Patent Application Publication
(10) Pub. No.: US 2026/0324129 A1
(43) Pub. Date: Oct. 15, 2026

(54) DETECTOR AND EQUIPMENT

(71) Applicant: CANON KABUSHIKI KAISHA, Tokyo (JP)

(72) Inventors: TOSHIO TOMIYOSHI, Kanagawa (JP); KATSUHISA MOCHIZUKI, Kanagawa (JP)

(21) Appl. No.: 19/638,999

(22) Filed: Apr. 3, 2026

(30) Foreign Application Priority Data
Apr. 9, 2025 (JP) 2025-064403

(51) Int. Cl. H10F 77/60; H10W 40/28

(52) U.S. Cl. CPC H10F 77/60; H10W 40/28

(57) ABSTRACT

A detector includes: a first member having a first surface and a second surface on opposite sides; a second member having a third surface and a fourth surface on opposite sides; a third member configured to connect the second surface and the third surface; and a cooling member arranged on the first surface. The first member includes a detecting region where a detecting element configured to detect an electromagnetic wave is arranged, and a peripheral circuit arranged outside the detecting region in a planar view, and the cooling member is arranged outside the detecting region in the planar view.

### BACKGROUND

### Field of the Technology

The present disclosure relates to a detector including a detecting element, and equipment using the same.

### Description of the Related Art

In a detector including a detecting element configured to detect an electromagnetic wave having a wavelength in the visible light or radiation region, power consumption increases along with an increase of the amount of signals to be processed or an increase of speed, and the heat generation amount may increase. Japanese Patent Laid-Open No. 2023-117516 discloses a structure that exhausts heat using a member having a high thermal conductivity.

### SUMMARY

The present disclosure provides a detector having a structure advantageous for suppressing an increase of a temperature.

According to one aspect of the present disclosure, there is provided a detector including: a first member having a first surface and a second surface on opposite sides; a second member having a third surface and a fourth surface on opposite sides; a third member configured to connect the second surface and the third surface; and a cooling member arranged on the first surface, wherein the first member includes a detecting region where a detecting element configured to detect an electromagnetic wave is arranged, and a peripheral circuit arranged outside the detecting region in a planar view, and wherein the cooling member is arranged outside the detecting region in the planar view.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a plan view of a detector according to the first embodiment;

FIG. 2 is a sectional view of the detector according to the first embodiment;

FIG. 3 is a sectional view showing the first member and the cooling member of the detector according to the first embodiment in an enlarged state;

FIG. 4 is a sectional view showing the configuration of a detector according to the second embodiment;

FIG. 5 is a sectional view showing the first member and the cooling member of a detector according to the third embodiment in an enlarged state;

FIG. 6 is a side view showing the configuration of a detector according to the fourth embodiment;

FIG. 7 is a side view showing the configuration of the detector according to the fourth embodiment;

FIG. 8 is a side view showing the configuration of a detector according to the fifth embodiment;

FIG. 9 is a top view showing the detector according to the fifth embodiment in a planar view viewed from the upper surface side;

FIG. 10 is a side view showing the configuration of a detector according to the sixth embodiment;

FIG. 11 is a side view showing the configuration of the detector according to the sixth embodiment;

FIG. 12 is a top view showing the detector according to the sixth embodiment in a planar view viewed from the upper surface side;

FIG. 13 is a top view showing the detector according to the embodiment in a planar view viewed from the upper surface side;

FIG. 14 is a top view showing the detector according to the embodiment in a planar view viewed from the upper surface side;

FIG. 15 is a top view showing the detector according to the embodiment in a planar view viewed from the upper surface side;

FIG. 16 is a top view showing the detector according to the embodiment in a planar view viewed from the upper surface side;

FIG. 17 is a top view showing the detector according to the embodiment in a planar view viewed from the upper surface side;

FIG. 18 is a top view showing the detector according to the embodiment in a planar view viewed from the upper surface side; and

FIG. 19 is a view schematically showing an example of application of the detector to equipment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

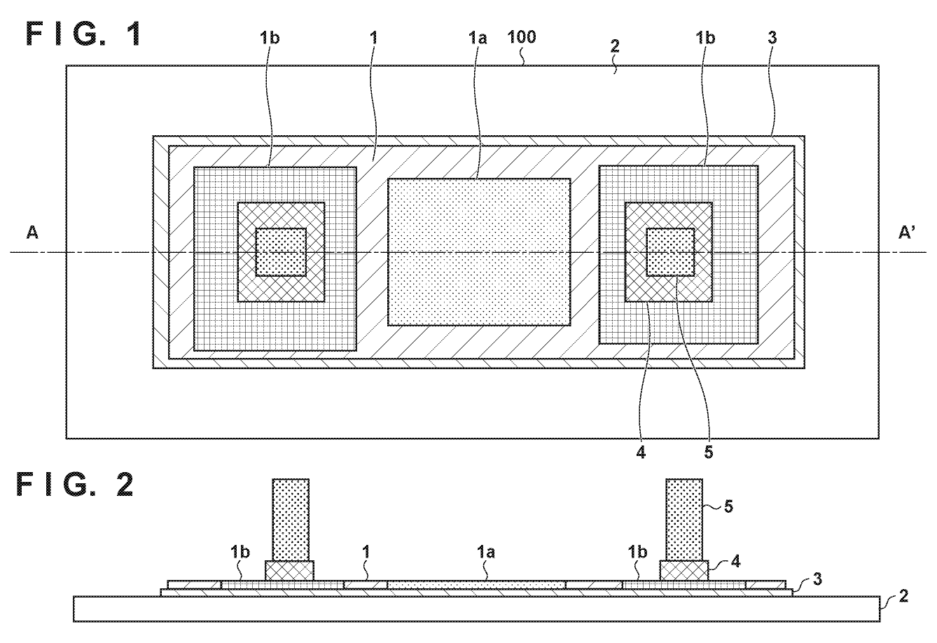

The first embodiment according to the present disclosure will now be described with reference to FIGS. 1, 2 and 3. FIGS. 1 and 2 schematically show the overall configuration of a detector 100 according to this embodiment. The detector 100 includes a detecting element capable of detecting an electromagnetic wave. The detector 100 is one of a Complementary Metal Oxide Semiconductor (CMOS) sensor and a Charge Coupled Device (CCD) sensor, which are representative image sensors. Also, a Single Photon Avalanche Diode (SPAD) may be used as the detecting element.

FIG. 1 is a top view showing the detector 100 in a planar view from the upper surface side. Here, a planar view indicates viewing the detector 100 from a direction perpendicular to a surface of the detector 100 to which an electromagnetic wave enters. When the surface of the detector 100 to which an electromagnetic wave enters is defined as an upper surface, the detector 100 may be viewed from the upper surface side, or may be viewed from the side of the lower surface that is the surface opposite to the surface to which an electromagnetic wave enters. FIG. 2 is a sectional view of the detector 100 taken along a line A - A' in FIG. 1.

The detector 100 includes a first member 1, a second member 2, a third member 3, a cooling member 4, and a heat transfer member 5. The first member 1 has two surfaces on the opposite sides. The second member 2 also has two surfaces on the opposite sides. The third member 3 is a member sandwiched between the first member 1 and the second member 2, and is a member that connects one surface of the first member 1 and one surface of the second member 2. The detector 100 includes a detecting region 1a in which an electromagnetic wave is detected, and a peripheral circuit 1b that processes a detected signal.

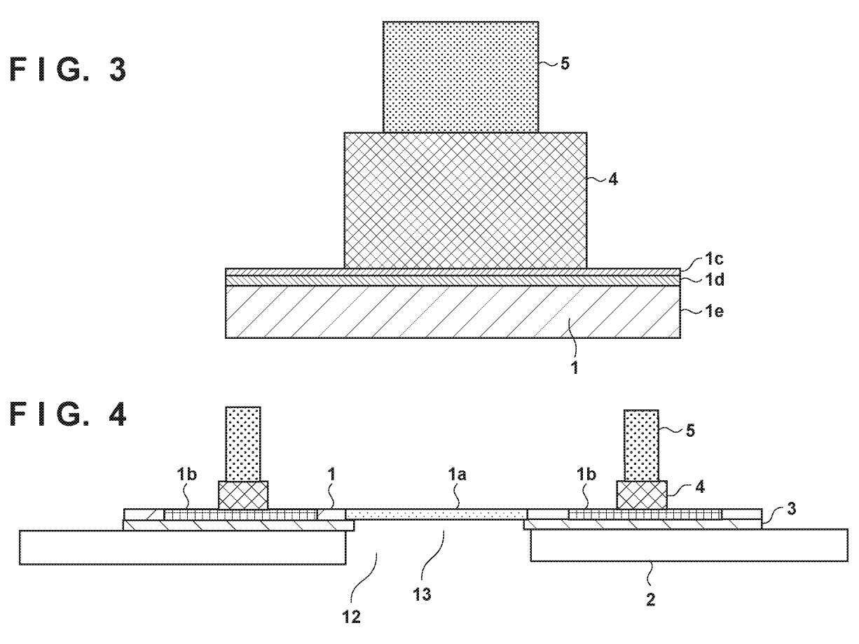

FIG. 3 is an enlarged view of cross sections of the first member 1, the cooling member 4, and the heat transfer member 5 along the line A - A' in FIG. 1. As shown in FIG. 3, the first member 1 includes an insulating film 1c, a circuit 1d, and a substrate 1e. As the substrate 1e, a single-crystal layer of silicon, germanium, or the like is used, but it may be a polycrystal layer. The planar shapes of the detecting region 1a and the peripheral circuit 1b of the first member 1 and the positional relationship therebetween are not particularly limited to those shown in FIG. 3. The peripheral circuit 1b is located on the periphery of the detecting region 1a, and one or a plurality of peripheral circuits 1b may be provided.

The detecting region 1a of the first member 1 is a part of a region where a detecting element configured to convert an electromagnetic wave into an output signal that is an electrical signal is arranged. If the detecting element is a pixel, the detecting region 1a can also be called a pixel region. In addition to a plurality of pixels configured to form an image based on an electromagnetic wave, the detecting region 1a of the first member 1 may include a readout circuit that reads out a signal from each pixel. In the planar view from the upper surface, the detecting region 1a generally has an outer periphery with a substantially rectangular shape. The detecting region 1a can have a structure in which the plurality of pixels and the readout circuit are arrayed. In the peripheral circuit 1b, a driving circuit, a control circuit, a signal processing circuit, an output circuit, and the like are provided.

The driving circuit can cause the pixels to perform image capturing or can control the readout circuit and cause it to read out a signal from each pixel. The control circuit can control the timings of the driving circuit, the signal processing circuit, and the like. The signal processing circuit can process the signal read out from the pixel. The output circuit is a circuit configured to output the processed signal from the detector 100. The peripheral circuit may be provided with an analog/digital converter (ADC) that converts the signal from the pixel into a digital signal.

The second member 2 is a circuit substrate made of a resin or ceramic and having a wiring layer in which wirings forming circuits are arranged. The second member 2 is larger than the outer shape of the first member 1 in the planar view and is electrically connected to the peripheral circuit 1b of the first member 1. Also, electric components (not shown) such as a capacitor, a resistor, and a connecting terminal are mounted on the second member 2 in some cases. A lot of circuit wirings and electric components are arranged in the second member 2, and the area of the second member 2 is generally larger than that of the peripheral circuit 1b in the planar view in order to mount the first member 1 thereon. However, the area can be made small by mounting some of the components forming circuits on another substrate.

The third member 3 is a bonding member that bonds one surface of the first member 1 and one surface of the second member 2. The third member 3 is an adhesive, grease, gel, solder, die bond material, or the like. From the viewpoint of preventing heat of the second member 2 from moving to the first member 1, a material having a high heat insulating property is appropriately used.

The cooling member 4 is arranged on the surface of the first member 1 on the opposite side of the surface bonded to the third member. The cooling member 4 is in contact with the insulating film 1c on the peripheral circuit 1b. The cooling member 4 can suppress an increase of the temperature of the detecting region 1a and the peripheral circuit 1b and lower the temperature. The cooling member 4 can be arranged immediately above the peripheral circuit 1b that is a heat generating source so as to cover a part or whole of the peripheral circuit 1b.

The heat transfer member 5 is in contact with the cooling member 4, and moves the heat from the detecting region 1a and the peripheral circuit 1b sequentially to the cooling member 4 and then to the heat transfer member 5 and exhausts the heat to the outside. To release heat, it is appropriate that the thermal conductivity of the heat transfer member 5 be higher than that of the third member 3 and the atmosphere outside the region where the detector 100 is arranged. As a material having a high thermal conductivity suitable for the heat transfer member, gold (Au), tungsten (W), copper (Cu), titanium (Ti), tantalum (Ta), aluminum (Al), ruthenium (Ru), carbon graphite, or the like can be used.

To release heat to the outside, the heat transfer member 5 may extend from the detector 100 and contact a member outside the detector 100. The heat transfer member 5 itself may be cooled by water. As the cooling member 4, a cooling device having a water cooling structure, a Peltier element to be electrically driven, or another cooling member that dissipates heat using thermal conduction may be used.

According to this embodiment, the cooling member 4 is brought into direct contact with the first member 1, thereby cooling the first member 1 without interposing the second member 2 and the third member 3. The first member 1 can thus efficiently be cooled. A temperature rise associated with heat generation may increase a dark current or noise with respect to the output signal of the detecting element. According to this embodiment, since the temperature rise of the first member 1 can be suppressed, generation of the dark current or noise in the detecting region 1a can be reduced. It is therefore possible to provide a detector 100 having a high S/N ratio. Also, according to this embodiment, it is possible to implement a simple cooling structure and cost reduction of the detector 100.

As the detecting element used in the detector 100 according to this embodiment, various types of detecting elements configured to detect an electromagnetic wave with a desired wavelength from infrared light, visible light, and radiation regions can be used. Radiation can include ionizing radiation such as X-rays and gamma rays. Radiation can also include particle beams such as alpha rays, beta rays, neutron rays, proton rays, heavy ion rays, and meson rays, as well as electron beams.

### Second Embodiment

The second embodiment will be described with reference to FIG. 4. FIG. 4 is a sectional view of a detector 100 according to this embodiment. In the second embodiment, a surface of a first member 1 in contact with a third member 3 will be defined as a reverse surface, and a surface on the opposite side will be defined as an obverse surface. A region formed by projecting a detecting region 1a of the first member 1 onto a second member 2 is defined as a first region. In a planar view, a region formed by partially opening a region of the second member 2 corresponding to the first region is defined as a first opening 12. Also, in the planar view, the third member 3 is arranged in at least a part of the overlapping region between the first member 1 and the second member 2. A region formed by opening a region of the third member corresponding to the first opening 12 is defined as a second opening 13.

The second member 2 and the third member 3 are respectively provided with the first opening 12 and the second opening 13 in which a part or whole of the detecting region 1a is exposed. If the detection target of the detector 100 is radiation, the radiation irradiates the obverse surface side of the first member 1 and passes to the reverse surface side. If the transmitted radiation is reflected or scattered, it results in noise in a detection signal. Hence, it is appropriate to form an opening in the reverse surface of the detecting region 1a. In addition, to prevent noise from increasing due to collision and scattering of the radiation, the use environment of the detector 100 can be a vacuum. The detector 100 may wholly be operated in a vacuum, but only a partial structure including the first region of the detector 100 may locally be operated in a vacuum. If the portions of the first opening 12 and the second opening 13 are a vacuum, the cooling efficiency in a vacuum can improve.

If the detecting region 1a is irradiated with radiation, secondary electrons are generated in the first member 1, crosstalk between pixels occurs due to the secondary electrons, and resolution may lower. If the first member 1 is thick, the secondary electrons are scattered, and the resolution lowers. On the other hand, if the detecting region 1a is thin, the detection amount is short, resulting in lowering of a signal. For the detector 100 to have an excellent S/N ratio, it is appropriate that the thickness of the detecting region 1a is 10 μm or more and 100 μm or less.

### Third Embodiment

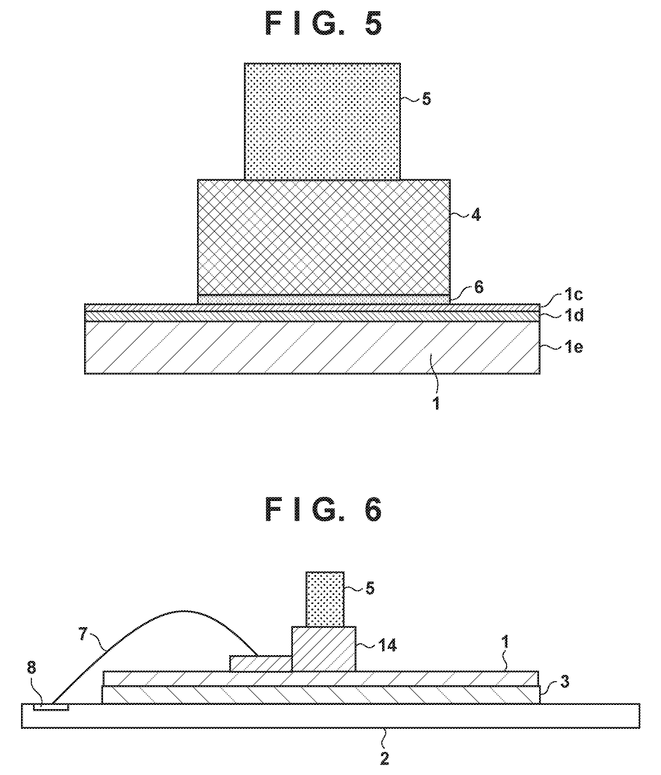

This embodiment will be described with reference to FIG. 5. FIG. 5 is an enlarged view of cross sections of a first member 1 and a cooling member 4 according to this embodiment. In the third embodiment, as shown in FIG. 5, the cooling member 4 is brought into contact with an insulating film 1c via a thermal conductive member 6 such as a heat dissipation putty, a heat transfer grease, or a thermal conductive sheet. By the thermal conductive member 6, the adhesion between the obverse surface of the first member 1 and the surface of the cooling member 4 on the cooling side can be improved. By interposing the thermal conductive member 6, the heat transfer efficiency between the cooling member 4 and the first member 1 improves, and the cooling efficiency improves. The structure according to this embodiment can be applied to the structure of the cooling portion in the first and second embodiments.

### Fourth Embodiment

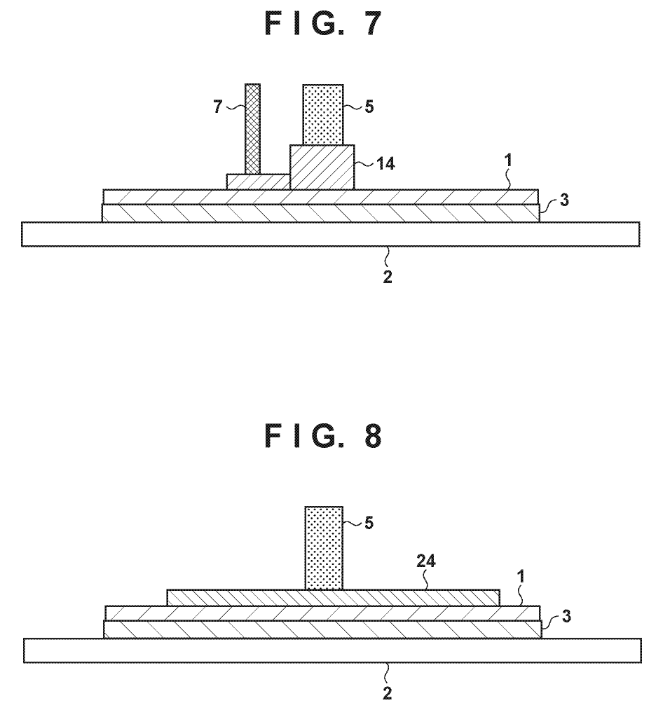

This embodiment will be described with reference to FIGS. 6 and 7. FIG. 6 is a side view showing the configuration of a detector 100 according to this embodiment. In this embodiment, a Peltier element 14 is used as a cooling member 4. The Peltier element 14 can move heat from the cooling side to the heat exhaust side by flowing a current. The temperature on the cooling side can be made lower than the temperature of the outside atmosphere.

In this embodiment, a current is supplied from an electrode pad 8 of a second member 2 to the Peltier element 14 that is the cooling member 4 via a wiring 7. Heat exhausted from the Peltier element can flow to the second member 2 as well via the wiring 7, and this is advantageous in exhausting heat in a case where the Peltier element 14 is used as the cooling member 4. When the Peltier element 14 is used as the cooling member 4, the temperature of a first member 1 can be made low. It is therefore possible to provide the detector 100 that reduces a dark current and generates little noise.

FIG. 7 shows an example in which a current is supplied directly from the outside to the Peltier element 14. A current is supplied from an external power supply to the Peltier element 14 that is the cooling member 4 via the conductive member 7. The conductive member 7 may be a power supply terminal configured to connect an external wiring. Since power can directly be supplied from the outside, it is unnecessary to form an electrode pad or a wiring to the electrode pad in the second member 2. Hence, since the wiring or circuit of the second member 2 need not be changed, it is suitable when applying a Peltier element to an existing detector 100.

### Fifth Embodiment

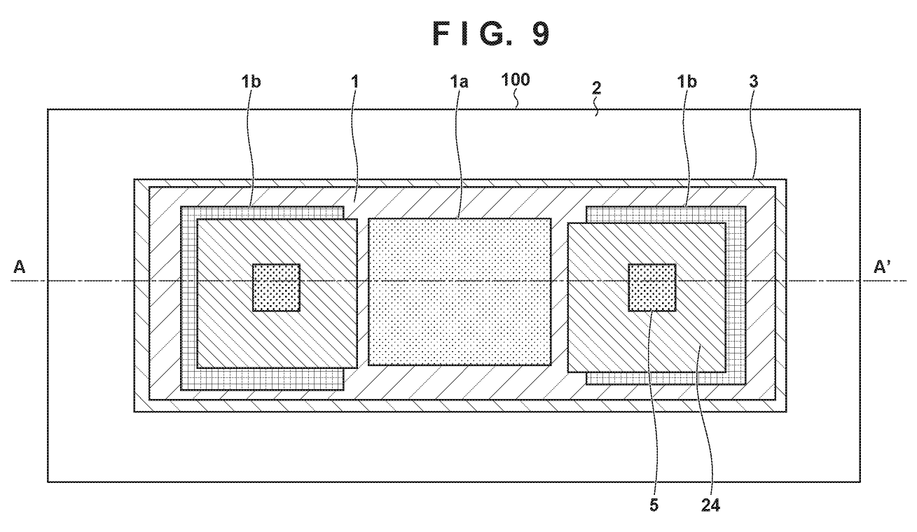

In this embodiment, a heat diffusion member 24 is used as a cooling member 4. FIG. 8 is a side view showing the configuration of a detector 100 according to this embodiment, and is a schematic sectional view taken along a line A - A' in FIG. 9. FIG. 9 is a schematic top view showing a first member 1 and the cooling member 4 in a planar view viewed from the side of the first member 1. The heat diffusion member 24 that is the cooling member 4 may cover at least a part of a peripheral circuit 1b of the first member 1, or the entire region of the peripheral circuit 1b may be covered with the heat diffusion member 24.

A heat transfer member 5 can be arranged on a surface of the heat diffusion member 24 on the opposite side of the surface in contact with the first member 1. In the example shown in FIG. 9, two peripheral circuits 1b are provided, but the number of peripheral circuits 1b may be one, or two or more. The cooling efficiency is increased by covering the heat generation area of the peripheral circuit 1b with the heat diffusion member 24 and increasing the heat absorption speed.

### Sixth Embodiment

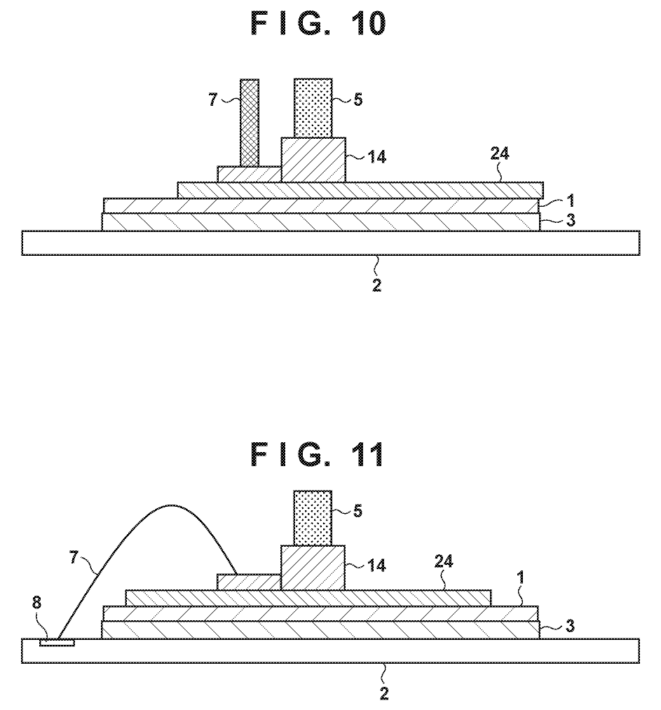

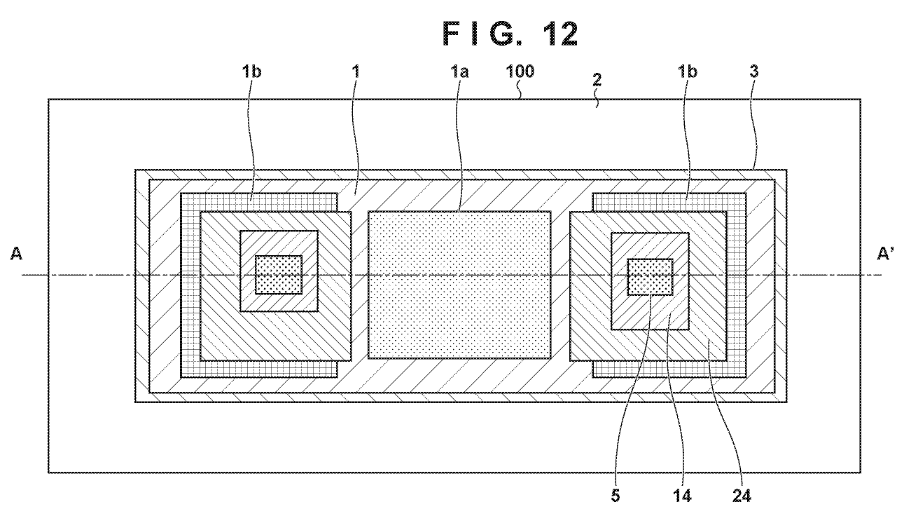

This embodiment will be described with reference to FIGS. 10, 11 and 12. FIGS. 10 and 11 are side views showing the configuration of a detector 100 according to this embodiment. These schematically correspond to a sectional view taken along a line A - A' in FIG. 12. FIG. 12 is a schematic top view showing a first member 1 and a cooling member in a planar view viewed from the upper surface side. The sixth embodiment shows a structure in which cooling is performed by combining a Peltier element 14 and a heat diffusion member 24, which correspond to the cooling members 4.

The cooling effect by the Peltier element 14 is diffused by the heat diffusion member 24 arranged to cover the heat generation area, thereby evenly cooling the obverse surface of the first member 1. For this reason, the temperature of the entire first member 1 can be stabilized. As a result, generation of a dark current or noise in a detecting region 1a of the first member 1 can be reduced, and a detector 100 having a high S/N ratio can be provided. As for a wiring 7 of the Peltier element to the power supply, power may directly be supplied from the outside, as shown in FIG. 10, or the internal wiring of a second member 2 may be used, as shown in FIG. 11.

### Arrangement of Cooling Member

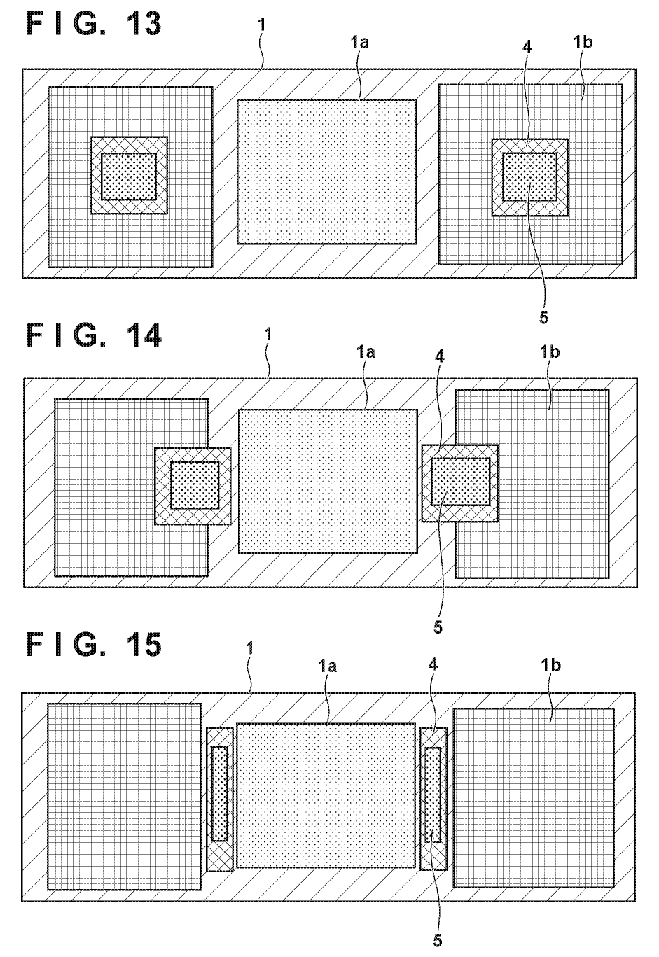

Variations of the arrangement of the cooling member 4 according to each of the above-described embodiments will be described with reference to FIGS. 13-18. Note that an example in which one or two peripheral circuits 1b are arranged is used for the descriptive convenience, but the number of peripheral circuits 1b may be one, or two or more.

FIG. 13 is a top view showing the detector 100 in a planar view viewed from the upper surface side. In this example, the cooling member 4 is arranged at the central position of the peripheral circuit 1b. The cooling member 4 need only cover the central position of the peripheral circuit 1b. In this example, the cooling member 4 is arranged inside the peripheral circuit 1b in the planar view. The cooling member 4 is arranged at the central position of the peripheral circuit 1b that is a heat generating source, thereby quickly exhausting generated heat and increasing the cooling efficiency to the generated heat.

FIG. 14 is a top view showing the detector 100 in a planar view viewed from the upper surface side. In the example shown in FIG. 14, the cooling member 4 is arranged on a side close to the detecting region 1a such that it covers a part of the peripheral circuit 1b and protrudes from the peripheral circuit 1b. When the cooling member 4 is arranged such that it protrudes from the peripheral circuit 1b to the side of the detecting region 1a, heat generated in the peripheral circuit 1b can be prevented from being transferred to the detecting region 1a. Also, according to this arrangement, since the cooling member 4 contributes to cooling of the detecting region 1a as well, it is possible to stabilize the temperature of the detecting region 1a and reduce a dark current. Hence, a detector 100 having a high S/N ratio can be provided.

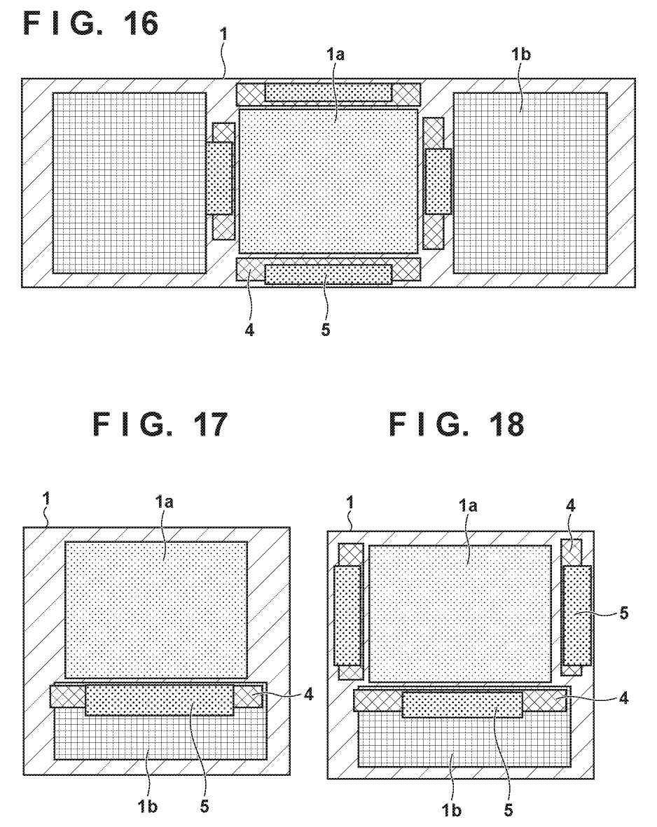

FIGS. 15 and 16 are top views showing the detector 100 according to the embodiment in a planar view viewed from the upper surface side. In the example shown in FIGS. 15 and 16, the cooling member 4 is arranged in a region between the detecting region 1a and the peripheral circuit 1b in the planar view. The cooling members 4 may be arranged in two directions in which two peripheral circuits 1b exist, as shown in FIG. 15, or may be arranged in all the four directions around the detecting region 1a, as shown in FIG. 16.

When the cooling members 4 are arranged on the periphery outside the detecting region 1a, heat generated in the peripheral circuits 1b can be blocked at the positions of the cooling members 4 and prevented from being transferred to the detecting region 1a, and the temperature of the detecting region 1a can be stabilized. As a result, it is possible to reduce the dark current in the detecting region 1a of the first member 1 and provide a detector 100 having a high S/N ratio.

FIGS. 17 and 18 are top views showing the detector 100 according to the embodiment in a planar view viewed from the upper surface side. In the example shown in FIG. 17, a heat generating source like the peripheral circuit 1b exists only in one direction. If the heat generating source exists in one direction, arranging one cooling member 4 between the detecting region 1a and the peripheral circuit 1b suffices, as shown in FIG. 17. Alternatively, as shown in FIG. 18, the cooling members 4 may be arranged between the detecting region 1a and the peripheral circuit 1b, and at a position that is outside and adjacent to the sides of the detecting region 1a while not being adjacent to the peripheral circuit 1b. This can further stabilize the temperature of the detecting region 1a. FIG. 18 shows an example in which the cooling members 4 are arranged on two sides that are adjacent to the detecting region 1a, but the cooling member 4 may be arranged on one side or on each of three sides.

### Example of Application of Detector to Equipment

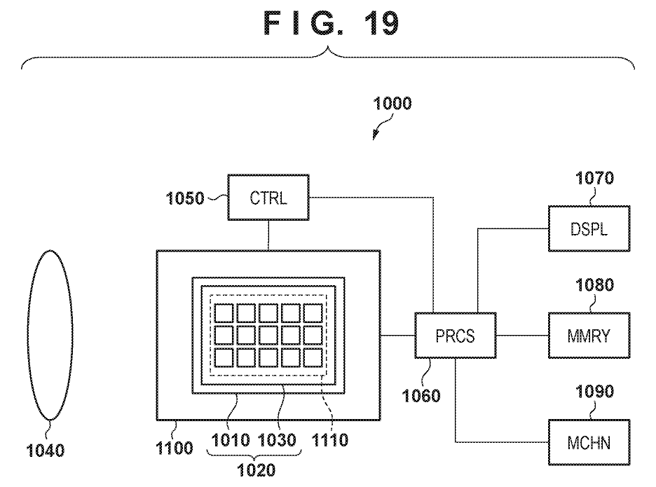

An example in which the detector according to the above-described embodiment is applied to equipment 1000 will be described with reference to FIG. 19. A semiconductor chip 1110 including detecting elements and placed on a package 1020 is mounted in the equipment 1000. A semiconductor device 1100 includes the detector according to the above-described embodiment in which a cooling member (not shown) is arranged. The semiconductor device 1100 can include the package 1020 including a base 1010 to which the semiconductor chip 1110 is fixed, and a light transmission member 1030 such as glass facing the semiconductor chip 1110. A connecting member such as a wire or a bump that connects an inner lead provided on the base 1010 and a terminal such as a pad electrode provided on the semiconductor chip 1110 can be arranged on the package 1020.

The equipment 1000 can include at least one of an optical device 1040, a control device 1050, a processing device 1060, a display device 1070, a memory device 1080, and a machine device 1090. The optical device 1040 is, for example, a lens, a shutter, or a mirror. The control device 1050 controls the semiconductor chip 1110. The control device 1050 is, for example, a semiconductor device such as an ASIC.

The processing device 1060 processes an output signal from a semiconductor integrated circuit included in the semiconductor chip 1110. The processing device 1060 is a semiconductor device such as a CPU or an ASIC configured to form an analog front end (AFE) or a digital front end (DFE). For example, the processing device 1060 may generate an image based on an image capturing signal at the time of event detection. The display device 1070 is an EL display device or a liquid crystal display device that displays an information image obtained by the semiconductor chip 1110. The memory device 1080 is a magnetic device or a semiconductor device that stores an information image obtained by the semiconductor chip 1110. The memory device 1080 is a volatile memory such as an SRAM or a DRAM or a nonvolatile memory such as a flash memory or a hard disk drive.

The machine device 1090 includes a movable portion or a propulsion unit such as a motor or an engine. In the equipment 1000, a signal output from the semiconductor chip 1110 is displayed on the display device 1070 or transmitted to the outside by a communication device (not shown) provided in the equipment 1000. For this purpose, the equipment 1000 may further include the memory device 1080 or the processing device 1060, separately from a storage circuit or an arithmetic circuit included in the semiconductor chip 1110. The machine device 1090 may be controlled based on a signal output from the semiconductor chip 1110.

The equipment 1000 is suitable for electronic equipment such as an information terminal having a shooting function, for example, a smartphone or a wearable terminal, or a camera, for example, a lens interchangeable type camera, a compact camera, a video camera, or a surveillance camera. The machine device 1090 in a camera may be a device capable of driving a component of the optical device 1040 for a zooming, focusing, or shutter operation. Alternatively, the machine device 1090 in a camera may be a device capable of moving the optical device 1040 for an anti-vibration operation.

Also, the equipment 1000 can be a transport equipment such as a vehicle or a ship. The machine device 1090 in a transport equipment can be used as a moving device. The equipment 1000 serving as a transport equipment is suitable for transporting the semiconductor chip 1110 or assisting and/or automating driving and steering by a shooting function. The processing device 1060 for assisting and/or automating driving and steering can perform processing for operating the machine device 1090 as a moving device based on information obtained by the semiconductor chip 1110. Alternatively, the equipment 1000 may be medical equipment such as an endoscope, measurement equipment such as a ranging sensor, analysis equipment such as an electron microscope, business equipment such as a copying machine, or industrial equipment such as a robot.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-064403, filed Apr. 9, 2025, which is hereby incorporated by reference herein in its entirety.

What is claimed is:

1. A detector comprising:
a first member having a first surface and a second surface on opposite sides;
a second member having a third surface and a fourth surface on opposite sides;
a third member configured to connect the second surface and the third surface; and
a cooling member arranged on the first surface,
wherein the first member includes a detecting region where a detecting element configured to detect an electromagnetic wave is arranged, and a peripheral circuit arranged outside the detecting region in a planar view, and
wherein the cooling member is arranged outside the detecting region in the planar view.

2. The detector according to claim 1, wherein
the second member includes an opening surrounding the detecting region in the planar view.

3. The detector according to claim 2, wherein
at least a region surrounded by the opening is a vacuum.

4. The detector according to claim 1, wherein
the third member is arranged in at least a part of an overlapping region between the first member and the second member in the planar view.

5. The detector according to claim 1, wherein
the cooling member is arranged to cover at least a part of the peripheral circuit in the planar view.

6. The detector according to claim 1, wherein
the cooling member is arranged between the peripheral circuit and the detecting region in the planar view.

7. The detector according to claim 1, wherein
at least a part of the first surface is covered with an insulating film.

8. The detector according to claim 7, wherein
the cooling member is in contact with the insulating film.

9. The detector according to claim 7, wherein
the cooling member is in contact with the insulating film via one of a heat dissipation putty, a heat transfer grease, or a thermal conductive sheet.

10. The detector according to claim 1, wherein
the cooling member includes an electrode to which a current for driving the cooling member is supplied, and
the electrode is connected to an electrode pad of the second member by a conductive member.

11. The detector according to claim 1, wherein
the cooling member is provided with a power supply terminal to which a current for driving the cooling member is supplied from an outside of the detector.

12. The detector according to claim 1, wherein
the first member contains silicon.

13. The detector according to claim 1, wherein
the second member includes a wiring layer in which a wiring is arranged, and the wiring is electrically connected to the first member.

14. The detector according to claim 1, wherein
the second member includes a ceramic.

15. The detector according to claim 1, wherein
the cooling member includes a Peltier element.

16. The detector according to claim 1, wherein
the cooling member includes a heat diffusion member.

17. The detector according to claim 1, wherein
the cooling member includes a Peltier element and a heat diffusion member, and the Peltier element is in contact with the first surface via the heat diffusion member.

18. An equipment comprising:
the detector according to claim 1; and
a processing device configured to process a signal from the detector.
